(19) United States
(12) Patent Application Publication
(10) Pub. No.: US 2026/0271730 A1
(43) Pub. Date: Sep. 10, 2026

(54) MANUFACTURING METHOD OF SEMICONDUCTOR DEVICE

(71) Applicant: Alliance Material Co., Ltd., Hsinchu County (TW)

(72) Inventors: Hsueh Chung Wu, Hsinchu County (TW); Chun Fa Chen, Hsinchu County (TW); Chi Hua Huang, Hsinchu County (TW); Chin Kai Lin, Hsinchu County (TW); Chen Ju Lee, Hsinchu County (TW); Shi Rou Xie, Hsinchu County (TW); Xuan You Chen, Hsinchu County (TW); Kuan Chun Hu, Hsinchu County (TW)

(73) Assignee: Alliance Material Co., Ltd., Hsinchu County (TW)

(21) Appl. No.: 19/310,895

(22) Filed: Aug. 26, 2025

(30) Foreign Application Priority Data
Mar. 4, 2025 (TW) 114107902

(51) Int. Cl. H01L 23/00

(52) U.S. Cl. CPC H10W 42/121

(57) ABSTRACT

A manufacturing method of a semiconductor device includes at least the following steps. A semiconductor structure is provided. The semiconductor structure includes a substrate, an interposer disposed on a first surface of the substrate, chips disposed on the interposer, and external terminals disposed on a second surface of the substrate. The interposer includes a molding layer and a conductive layer buried in the molding layer. The chips are electrically connected to the external terminals through the interposer and the substrate. Next, a bonding process is performed, so that an adhesive film covers the external terminals. The adhesive film is used to provide an inward pulling force on the semiconductor structure. Then, a baking process is performed on the semiconductor structure and the adhesive film thereon. A temperature of the baking process is less than 300° C. The adhesive film is removed.

### CROSS-REFERENCE TO RELATED APPLICATION

This application claims the priority benefit of Taiwan application serial no. 114107902, filed on Mar. 4, 2025. The entirety of the above-mentioned patent application is hereby incorporated by reference herein and made a part of this specification.

### BACKGROUND

### Technical Field

The disclosure relates to a manufacturing method of a semiconductor device.

### Description of Related Art

Generally speaking, a high temperature process (for example, much higher than 300° C.) are often required during a manufacturing process of a semiconductor structure. Due to the mismatch in coefficient of thermal expansions between different components, warping may easily occur during the repeated heating and cooling manufacturing process, thereby affecting product yield.

### SUMMARY

The disclosure provides a manufacturing method of a semiconductor device, which effectively improves warping of a semiconductor structure, thereby increasing production yield of a product.

A manufacturing method of a semiconductor device of the disclosure includes at least the following steps. A semiconductor structure is provided. The semiconductor structure includes a substrate, an interposer disposed on a first surface of the substrate, multiple chips disposed on the interposer, and multiple external terminals disposed on a second surface of the substrate. The interposer includes a molding layer and a conductive layer buried in the molding layer. The chips are electrically connected to the external terminals through the interposer and the substrate. Next, a bonding process is performed, so that the adhesive film covers the external terminals. The adhesive film is used to provide an inward pulling force on the semiconductor structure. Then, a baking process is performed on the semiconductor structure and the adhesive film thereon. A temperature of the baking process is less than 300° C. The adhesive film is removed.

In an embodiment of the disclosure, before the bonding process is performed, at least one axial tension is provided to the adhesive film to provide the pulling force after the bonding process is performed.

In an embodiment of the disclosure, a value range of the tension is between 1 N/cm and 30 N/cm.

In an embodiment of the disclosure, the at least one axial direction is an X-axis, a Y-axis, or a combination thereof.

In an embodiment of the disclosure, the adhesive film is composed of a first base material and a first adhesion layer, the first adhesion layer is disposed between the substrate and the first base material, and a material of the first base material includes polyimide.

In an embodiment of the disclosure, the adhesive film includes a regulating layer, a value range of a coefficient of thermal expansion of the regulating layer is between 20 ppm/° C. and 300 ppm/° C., and after the baking process is performed, the regulating layer provides the pulling force.

In an embodiment of the disclosure, the adhesive film is composed of a second adhesion layer and the regulating layer, and the adhesive film is bonded to the semiconductor structure through the second adhesion layer.

In an embodiment of the disclosure, the regulating layer includes polyetherimide, polyetheretherketone, polyphenylene sulfide, polyethylene naphthalate, or a combination thereof.

In an embodiment of the disclosure, the adhesive film is composed of a second base material, a third adhesion layer, and the regulating layer. The adhesive film is bonded to the semiconductor structure through the third adhesion layer. The third adhesion layer is disposed between the semiconductor structure and the second base material. The second base material is disposed between the third adhesion layer and the regulating layer.

In an embodiment of the disclosure, the second base material includes polyimide, and the second regulating layer includes epoxy molding compound, phenolic resin, or a combination thereof.

Based on the above, the disclosure may effectively regulate the warping state of the semiconductor structure through the synergistic effect between the pulling force continuously provided by the adhesive film after being bonded to the semiconductor structure and the softening phenomenon of the molding layer after the baking process in the case where the baking process is stopped and the temperature is gradually lowered, so that the upwardly warped semiconductor structure receives the reverse stress during the cooling process and shrinks downward to approach the horizontal state. In this way, warping of the semiconductor structure may be effectively reduced, thereby improving the production yield of the product.

In order for the features and advantages of the disclosure to be more comprehensible, the following specific embodiments are described in detail in conjunction with the drawings.

### BRIEF DESCRIPTION OF THE DRAWINGS

FIG. 1 is a flowchart of a manufacturing method of a semiconductor device according to some embodiments of the disclosure.

FIG. 2 is a schematic diagram of an adhesive film bonded to a semiconductor structure according to some embodiments of the disclosure.

FIG. 3 is a schematic diagram of a regulating process of the adhesive film and the semiconductor structure according to some embodiments of the disclosure.

FIG. 4 is a schematic diagram of the adhesive film and the semiconductor structure after regulation according to some embodiments of the disclosure.

FIG. 5 is a schematic diagram of an intermediate stage of a manufacturing method of a semiconductor device according to some embodiments of the disclosure.

FIG. 6 is a schematic cross-sectional diagram of an adhesive film used in FIG. 5 according to an embodiment.

FIG. 7 is a schematic diagram of an intermediate stage of a manufacturing method of a semiconductor device according to some embodiments of the disclosure.

FIG. 8 is a schematic cross-sectional diagram of an adhesive film used in FIG. 7 according to an embodiment.

FIG. 9 is a schematic cross-sectional diagram of the adhesive film used in FIG. 7 according to another embodiment.

### DESCRIPTION OF THE EMBODIMENTS

The disclosure will be more fully described with reference to the drawings of the embodiments. However, the disclosure may be embodied in many different forms and should not be construed as being limited to the embodiments described herein. The thickness, the size, or dimensions the of layers or regions in the drawings may be exaggerated for clarity. The same or similar reference numerals represent the same or similar elements, which will not be reiterated one by one in the following paragraphs.

Unless otherwise specified, the term “between” for defining a value range in the specification is intended to cover a range equal to and between endpoint values. For example, a size range between a first value and a second value means that the size range may cover the first value, the second value, and any value between the first value and the second value.

Unless otherwise defined, all terms (including technical and scientific terms) used herein have the same meanings as commonly understood by persons of ordinary skill in the art to which the disclosure belongs.

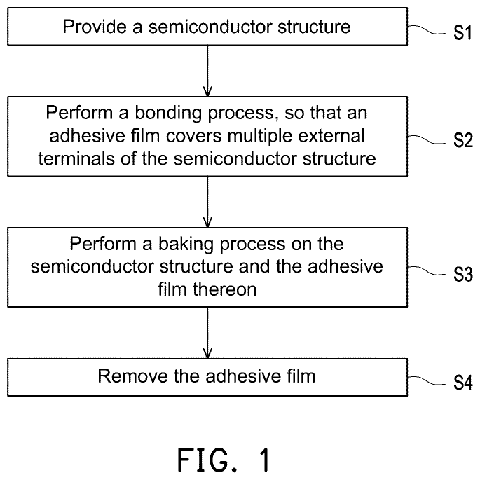

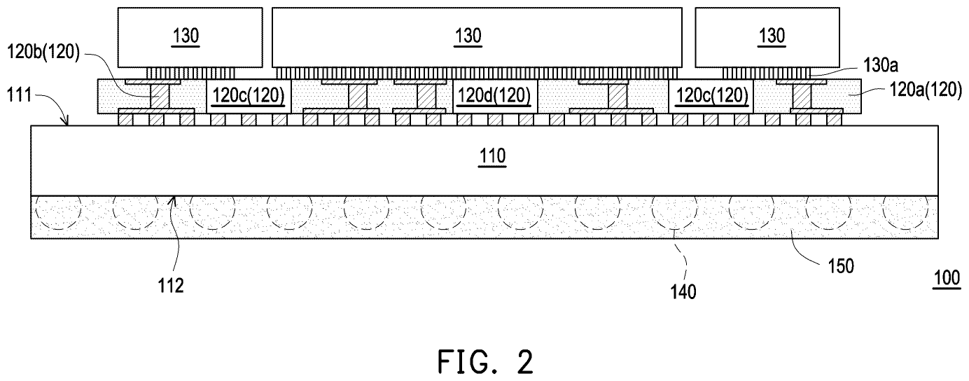

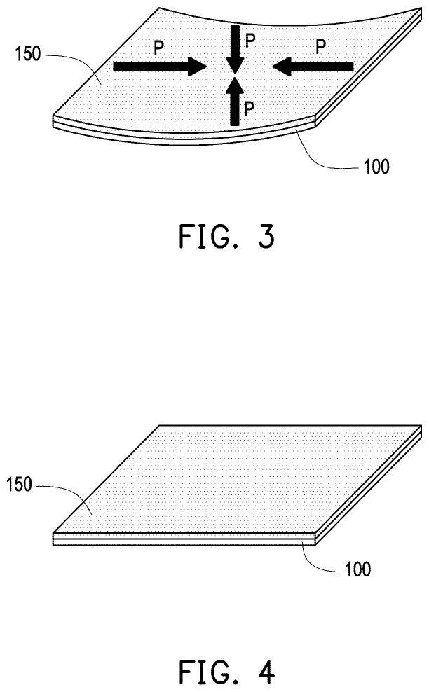

FIG. 1 is a flowchart of a manufacturing method of a semiconductor device according to some embodiments of the disclosure. FIG. 2 is a schematic diagram of an adhesive film bonded to a semiconductor structure according to some embodiments of the disclosure. FIG. 3 is a schematic diagram of a regulating process of the adhesive film and the semiconductor structure according to some embodiments of the disclosure. FIG. 4 is a schematic diagram of the adhesive film and the semiconductor structure after regulation according to some embodiments of the disclosure. It should be noted that, for the sake of clarity, FIG. 2 does not show an upward warping state, and the corresponding warping state may be as shown in FIG. 3.

Please refer to FIG. 1 to FIG. 4. Corresponding to step S1, a semiconductor structure 100 is provided. For example, the semiconductor structure 100 includes a substrate 110 having a first surface 111 and a second surface 112, an interposer 120 disposed on the first surface 111, multiple chips 130 disposed on the interposer 120, and multiple external terminals 140 disposed on the second surface 112. In an embodiment, the substrate 110 includes a conductive circuit (not shown), the interposer 120 includes a molding layer 120a and a conductive layer 120b (for example, including a through insulating via (TIV)) buried in the molding layer 120a, and multiple bumps 130a are formed on the chips 130. In this way, the bumps 130a on the chips 130 may be electrically connected to the external terminals 140 through the conductive layer 120b of the interposer 120 and a conductive circuit of the substrate 110, but the disclosure is not limited thereto. The chips 130 may also be connected to the external terminals 140 through other suitable conductive paths. In addition, the interposer 120 may also include a bridge chip 120c and a power chip 120d, wherein the bridge chip 120c may electrically connect the chips 130 to each other, but the disclosure is not limited thereto. Here, the semiconductor structure 100 may be fan-out wafer level packaging (FOWLP) or fan-out panel-level packaging (FOPLP).

Furthermore, due to the mismatch in coefficient of thermal expansions of materials between the molding layer 120a and the conductive layer 120b, upward warping (for example, a middle part of the semiconductor structure 100 is concave toward the direction of the external terminals 140 and presents a smiling face shape) may occur during a manufacturing process due to a high temperature process (for example, much higher than 300° C.), thereby affecting production yield of a product. Therefore, in the disclosure, warping caused by the mismatch in the coefficient of thermal expansions of the materials between the molding layer 120a and the conductive layer 120b is targeted. Therefore, the disclosure does not limit specific details (for example, materials, formation methods, etc.) of conventional components in the semiconductor structure 100, such as the substrate 110, other elements in the interposer 120, the chips 130, and the external terminals 140. The configuration of the components in the drawings is only an exemplary description. In other words, the substrate 110, other elements in the interposer 120, the chips 130, and the external terminals 140 and the configuration relationships therebetween may be selected according to actual product requirements, which all fall within the protection scope of the disclosure, as long as the interposer 120 of the semiconductor structure 100 has the molding layer 120a and the conductive layer 120b that may warp. Here, the material of the molding layer 120a includes epoxy molding compound (EMC), silicone molding compound (SMC), or other molding materials suitable for molding processes, and the material of the conductive layer 120b includes copper or a similar conductive material.

Next, in order to improve warping of the semiconductor structure 100, corresponding to step S2, a bonding process is performed, so that the adhesive film 150 covers the external terminals 140, and corresponding to step S3, a baking process is performed on the semiconductor structure 100 and the adhesive film 150 thereon, wherein the temperature of the baking process is less than 300° C., and the adhesive film 150 is used to provide an inward pulling force P on the semiconductor structure 100, as shown in FIG. 3. Accordingly, as shown in FIG. 4, through a synergistic effect between the pulling force P continuously provided by the adhesive film 150 after being bonded to the semiconductor structure 100 and a softening phenomenon of the molding layer 120a after the baking process, in the case where the baking process is stopped and the temperature is gradually lowered, the warping state of the semiconductor structure 100 may be effectively regulated, so that the upwardly warped semiconductor structure 100 receives a reverse stress during the cooling process and shrinks downward to approach a horizontal state. In this way, warping of the semiconductor structure 100 may be effectively improved, thereby improving the production yield of the product. In addition, after cooling (for example, cooling to room temperature), corresponding to step S4, the adhesive film 150 may be removed through a suitable manner (for example, room temperature or heating to 40° C., 60° C., or 80° C.).

It should be noted that although the semiconductor structure 100 shown in FIG. 4 shrinks to approach the horizontal state, the disclosure is not limited. The degree of shrinking of the semiconductor structure 100 may be determined according to actual conditions, which all fall within the protection scope of the disclosure, as long as the pulling force P reverse to warping is received by the semiconductor structure 100. In addition, the disclosure limits the temperature of the baking process to less than 300° C. Under the temperature design, the pulling force P reverse to warping is much greater than the stress of the semiconductor structure 100 warping upward again, so warping of the semiconductor structure 100 may be effectively reduced.

In some embodiments, the adhesive film 150 covers the external terminals 140. In other words, the external terminals 140 are completely embedded in the adhesive film 150 and are not exposed. In this way, the warpage regulating effect of the adhesive film 150 may be further improved, wherein the baking temperature of the baking process is lower than the softening temperature of the external terminals 140, but the disclosure is not limited thereto. Optionally, in an embodiment not shown, a primer is further included between a chip and an interposer and between the interposer and a substrate to protect electrical connectors therebetween.

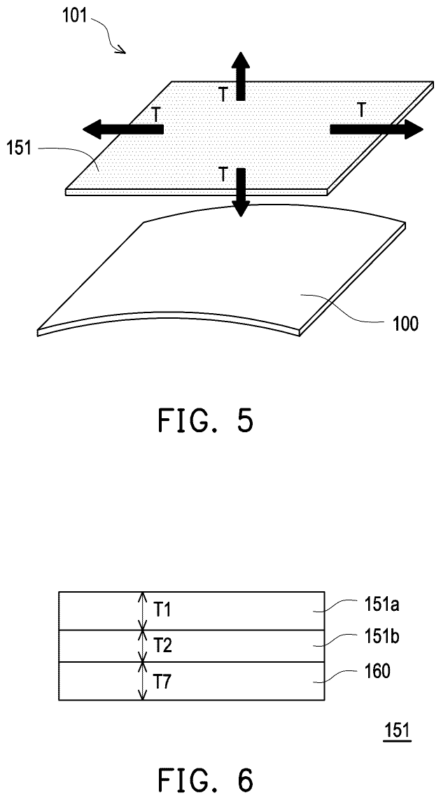

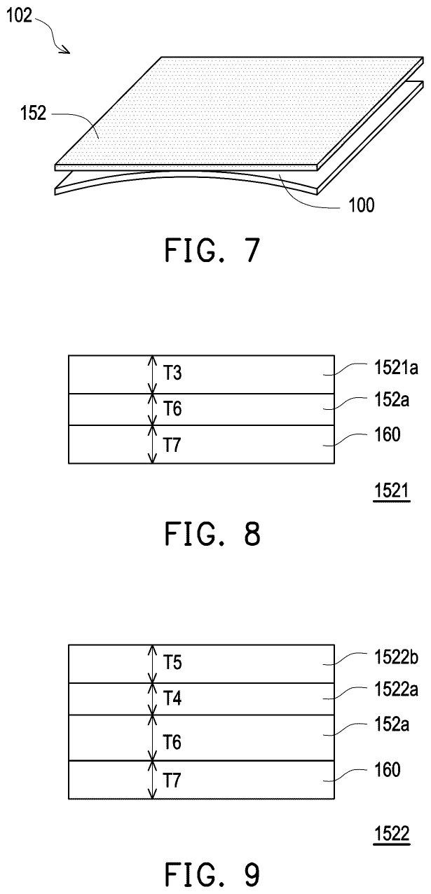

FIG. 5 is a schematic diagram of an intermediate stage of a manufacturing method of a semiconductor device according to some embodiments of the disclosure. FIG. 6 is a schematic cross-sectional diagram of an adhesive film used in FIG. 5 according to an embodiment. FIG. 7 is a schematic diagram of an intermediate stage of a manufacturing method of a semiconductor device according to some embodiments of the disclosure. FIG. 8 is a schematic cross-sectional diagram of an adhesive film used in FIG. 7 according to an embodiment. FIG. 9 is a schematic cross-sectional diagram of the adhesive film used in FIG. 7 according to another embodiment.

FIG. 5 to FIG. 9 will be used to respectively disclose specific implementation of the intermediate stages of the manufacturing method of various semiconductor devices, but are not intended to limit the disclosure, which all fall within the protection scope of the disclosure, as long as there is a synergistic effect between a pulling force generated by an adhesive film on a semiconductor structure and a softening phenomenon of a molding layer after a baking process, wherein FIG. 5 and FIG. 6 are used to illustrate specific implementation of generating the inward pulling force P on the semiconductor structure 100 through introducing an external force and the adhesive film used therewith, and FIG. 7 to FIG. 9 are used to illustrate specific implementation of generating the inward pulling force P on the semiconductor structure 100 through characteristics of a material and the adhesive film used therewith.

In the embodiment of FIG. 5, stage 101 before a bonding process is performed is shown, and the adhesive film 150 of FIG. 2 to FIG. 4 may be implemented through an adhesive film 151. For example, before the adhesive film 151 is bonded to the semiconductor structure 100, at least one axial tension T may be provided to the adhesive film 151. In this way, the adhesive film 151 having the tension T may rebound and shrink when bonded to the semiconductor structure 100 to generate the inward pulling force P on the semiconductor structure 100, so as to flatten the upwardly warped semiconductor structure 100. Afterwards, during the baking process, when the molding layer 120a softens, the adhesive film 151 may continue to maintain the inward shrinking force, and continue to provide the reverse stress to the semiconductor structure 100, so that warping may be effectively reduced.

In some embodiments, the value range of the tension T is between 1 Newton/centimeter (N/cm) to 30 N/cm, and at least one axial direction is the X-axis, the Y-axis, or a combination thereof. For example, the tension T may be introduced in one or more axial directions, and the tension T in the axial directions may be the same or different. Therefore, by adopting such manner, warping at different positions on the semiconductor structure 100 may be adjusted to achieve an improved regulating effect. Based on this, when the semiconductor structure 100 has a structure with a long side and a short side, the tension film bonding manner of the disclosure may be more competitive. Here, the tension T may be provided by a suitable tension film bonding apparatus, and the disclosure is not limited thereto. For example, the tension film bonding apparatus may have a clamp, and the adhesive film 151 may be first clamped by the clamp and given the required tension T through a displacement of the clamp or the clamp being subjected to air pressure, and then bonded to the semiconductor structure 100. However, it should be noted that the displacement corresponding to the tension T may be determined according to the actual product, and the disclosure is not limited thereto.

In the embodiment, since the manner for regulating warpage is based on the introduction of the external force (tension T), the adhesive film 151 used may not experience significant shrinkage. For example, in FIG. 6, the adhesive film 151 is composed of a base material 151a and an adhesion layer 151b. The base material 151a may be bonded to the semiconductor structure 100 through the adhesion layer 151b, and the material of the base material 151a may include polyimide (PI) with good heat resistance but poor shrinkage. On the other hand, a thickness T1 of the base material 151a is between 0.025 mm and 0.125 mm (for example, 0.05 mm), but the disclosure is not limited thereto.

In addition, the material of the adhesion layer 151b includes butyl rubber, isoprene rubber, chloroprene rubber, ethylene-vinyl acetate copolymer, ethylene-acrylic acid copolymer, ethylene-acrylate copolymer, polybutadiene resin, polycarbonate resin, thermoplastic polyimide resin, phenoxy resin, acrylic resin, polyethylene terephthalate, saturated polyester resin of polybutylene terephthalate, fluorocarbon resin, or a combination thereof, and a thickness T2 of the adhesion layer 151b is between 0.01 mm and 0.1 mm (for example, 0.1 mm), but the disclosure is not limited thereto.

In the embodiment of FIG. 7, stage 102 is shown as being between performing the bonding process and performing the baking process, and the adhesive film 150 of FIG. 2 to FIG. 4 may be implemented through an adhesive film 152. For example, the adhesive film 152 has a regulating layer, and the value range of the coefficient of thermal expansion (CTE) of the regulating layer is between 20 ppm/° C. and 300 ppm/° C. In this way, before the baking process is performed, even if the regulating layer is already bonded to the semiconductor structure 100, the regulating layer does not provide the pulling force P at this time, as shown in FIG. 7. After performing the baking process, the regulating layer shrinks based on the material characteristics, thereby providing the pulling force P to the semiconductor structure 100, so as to flatten the upwardly warped semiconductor structure 100. At the same time, during the baking process, when the molding layer 120a softens, the adhesive film 152 may continue to maintain the inward shrinking force, and continue to provide the reverse stress to the semiconductor structure 100, so that warping may be effectively reduced.

In an embodiment, as shown in FIG. 8, the adhesive film 152 may be an adhesive film 1521, which may be composed of an adhesion layer 152a and a regulating layer 1521a. The regulating layer 1521a may be bonded to the semiconductor structure 100 through the adhesion layer 152a, wherein the regulating layer 1521a includes polyetherimide (PEI), polyetheretherketone (PEEK), polyphenylene sulfide (PPS), polyethylene naphthalate (PEN), or a combination thereof with a larger coefficient of thermal expansion, thereby having better shrinkage, and the material of the regulating layer 1521a may not include polyimide. For example, when the temperature of the baking process is greater than 200° C., polyetherimide and polyetheretherketone are preferred, and when the temperature of the baking process is less than 200° C., polyphenylene sulfide and polyethylene naphthalate are preferred, but the disclosure is not limited thereto. For example, in terms of the selection of the above materials, the baking temperature and the warpage control ability increase in a linear relationship. In other words, in terms of the selection of the above materials, the adhesive film 1521 may have good thermal stability, which may further improve product yield, but the disclosure is not limited thereto.

On the other hand, when a thickness T3 of the regulating layer 1521a is thicker, the warpage regulating ability thereof is also improved accordingly. For example, the thickness of the regulating layer 1521a may be between 35 μm and 350 μm (for example, 0.05 mm), but the disclosure is not limited thereto.

In another embodiment, as shown in FIG. 9, the adhesive film 152 may be an adhesive film 1522, which may be composed of a base material 1522a, the adhesion layer 152a, and a regulating layer 1522b. The adhesive film 1522 is bonded to the semiconductor structure 100 through the adhesion layer 152a. The adhesion layer 152a is disposed between the semiconductor structure 100 and the base material 1522a. The base material 1522a is disposed between the adhesion layer 152a and the regulating layer 1522b, wherein the base material 1522a includes polyimide, and the regulating layer 153B includes epoxy molding compound, phenolic resin, or a combination thereof with better shrinkage. Here, a thickness T4 of the base material 1522a is between 0.025 mm and 0.1 mm, and a thickness T5 of the regulating layer 1522b is between 0.035 mm and 0.35 mm, but the disclosure is not limited thereto.

In some embodiments, a thickness T6 of the adhesion layer 152a in the adhesive films 1521 and 1522 is between 0.01 mm and 0.1 mm (for example, 0.01 mm), and the adhesion layer 152a includes an adhesive composition. The adhesive composition includes an acrylic curable compound and a functional monomer in a suitable ratio.

In some embodiments, a monomer of the acrylic curable compound may be a compound having a (meth)acrylate group. For example, the (meth)acrylate-based compound may include a compound selected from compounds composed of methyl(meth)acrylate, ethyl(meth)acrylate, n-propyl(meth)acrylate, isopropyl(meth)acrylate, n-butyl(meth)acrylate, t-butyl(meth)acrylate, sec-butyl(meth)acrylate, pentyl(meth)acrylate, 2-ethylhexyl(meth)acrylate, 2-ethylbutyl(meth)acrylate, n-octyl(meth)acrylate, isooctyl(meth)acrylate, isononyl(meth)acrylate, lauryl(meth)acrylate, tetradecyl(meth)acrylate, acrylic acid, methacrylic acid, 2-(meth)acryloyloxy acetic acid, 3-(meth)acryloyloxy propyl acid, 4-(meth)acryloyloxy butyric acid, 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 2-hydroxy ethylene glycol(meth)acrylate, 2-hydroxy propylene glycol(meth)acrylate, and a combination thereof.

In some embodiments, the acrylic curable compound may be an acrylic photocurable compound, and the adhesive composition may further include a photoinitiator. For example, the photoinitiator is an organic photoinitiator such as oxime (for example, acyloxime, ketoneoxime, or other oximes), benzoin and derivatives (for example, benzoin, benzoin dimethyl ether, benzoin ethyl ether, benzoin isopropyl ether, benzoin butyl ether), benzil, alkyl phenone (for example, α-hydroxyalkyl phenone (HAPK)), acyl phosphorus oxide (for example, alkyl diacyl phosphine oxide), and benzophenone, thioxanthen-9-one; a cationic photoinitiator such as diazonium salt, diaryliodonium salt, triarylsulfonium salt, alkylsulfonium salt, aromatic iron salt, sulfonyl ketone, and triarylsiloxane; a derivative thereof, or a combination thereof.

In some embodiments, the functional monomer may be a bridging agent, a heat-resistant monomer, and/or a diluent monomer.

In some embodiments, the adhesive composition is organic solvent-free. The organic solvent is, for example, n-hexane, toluene, xylene, methyl isobutyl ketone, etc., which may be used alone or in combination. In this way, the adhesion layer 152a may reduce contamination of a semiconductor manufacturing process (for example, baking, heating deposition, exposure and development, or other semiconductor manufacturing processes with high temperature or low pressure) when used during the process.

In some embodiments, the adhesion layer 152a is, for example, a pressure-sensitive adhesive. For example, the material of the adhesion layer 152a includes acrylic resin, polyurethane resin, polysiloxane resin, a combination of the above materials, or other suitable polymer materials.

In some embodiments, the adhesion layer 152a may include a photosensitive material, and adhesion of the adhesion layer 152a is reduced after being exposed to light (for example, ultraviolet light), so that the adhesive may be removed by light exposure during a subsequent process. Alternatively, the adhesion layer 152a may include a thermosetting material, and adhesion of the adhesion layer 152a is reduced after being heated, so that the adhesive may be removed by heating during a subsequent process. Alternatively, the adhesion layer 152a may include a cold dissociation material, and adhesion of the adhesion layer 152a is reduced when cooled below the glass transition temperature, so that the adhesive may be removed by cooling during a subsequent process.

The adhesion layer 152a is suitable for adhering the dissociated material layer 152a to an adhered object (for example, a process element). The adherence manner between the adhesion layer 152a and other materials includes physical adsorption, diffusion, electrostatic adsorption, mechanical interlocking, and chemical bonding.

In some embodiments, the raw materials of the adhesion layer 152a include an oligomer, a monomer, an initiator, and an additive. For example, the cured adhesion layer 152a includes acrylic resin or other suitable materials. In some embodiments, the oligomer includes polyester acrylate, polyurethane acrylate, polyether acrylate, or a combination thereof.

In some embodiments, in the raw materials of the adhesion layer 152a, the weight ratio of the monomer is 20 wt % to 50 wt %, such as 20 wt %, 30 wt %, 40 wt %, 50 wt %, or any range from 20 wt % to 50 wt %. In some embodiments, the monomer includes a monofunctional monomer, a bifunctional monomer, a multifunctional monomer, or a combination thereof.

In some embodiments, the monofunctional monomer is, for example, isodecyl acrylate (IDA), tetrahydrofurfuryl acrylate (THFA), isobornyl acrylate (IBOA), or 2-phenoxy ethyl acrylate (PHEA), wherein the chemical structures of isodecyl decaacrylate, tetrahydrofurfuryl acrylate, isobornyl acrylate, and 2-phenoxy ethyl acrylate are respectively shown in (Formula 2), (Formula 3), (Formula 4), and (Formula 5) below.

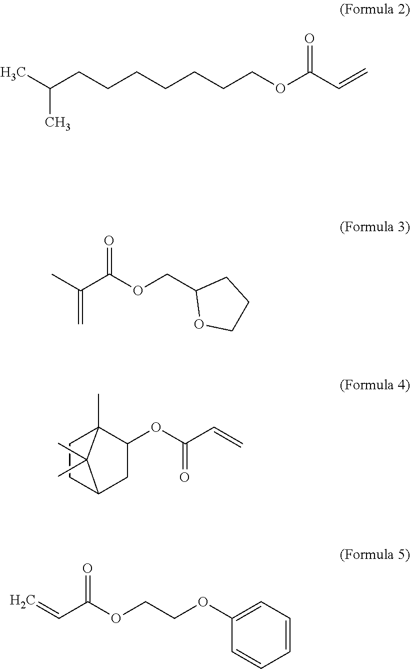

In some embodiments, the bifunctional monomer is, for example, hexanediol diacrylate (HDDA) or polyethylene glycol (600) diacrylate (PEG(600)DA), wherein the chemical structures of hexanediol diacrylate and polyethylene glycol (600) diacrylate are respectively shown in (Formula 6) and (Formula 7) below.

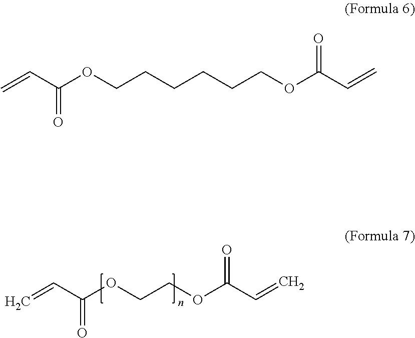

In some embodiments, the multifunctional monomer is, for example, trimethylolpropane triacrylate (TMPTA) or dipentaerythritol hexaacrylate (DPHA), wherein the chemical structures of trimethylolpropane triacrylate and dipentaerythritol hexaacrylate are respectively shown in (Formula 8) and (Formula 9) below.

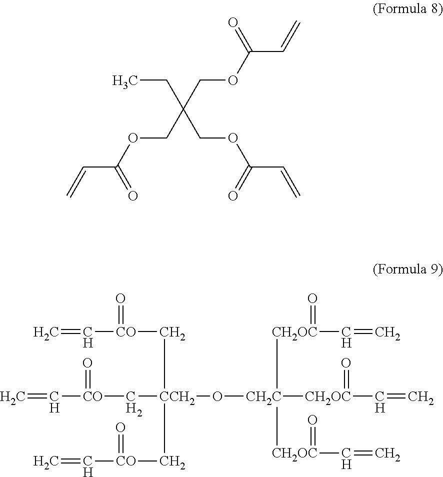

The initiator among the raw materials of the adhesion layer 152a is suitable for initiating polymerization and bridging reactions. For example, one or more photoinitiators are used to induce the polymerization and bridging reactions of the monomer and the oligomer. In some embodiments, the photoinitiator includes a free radical photoinitiator. In some embodiments, in the raw materials of the adhesion layer 152a, the weight ratio of the photoinitiator is less than or equal to 10 wt %, such as 9 wt %, 8 wt %, 7 wt %, 6 wt %, 5 wt %, 4 wt %, 3 wt %, 2 wt %, 1 wt %, or any value below 10 wt %. In some embodiments, the photoinitiator is suitable for absorbing ultraviolet light to initiate the polymerization reaction.

In some embodiments, polyester acrylate resin, polyurethane acrylate resin, or polyether acrylate resin uses the free radical photoinitiator, such as 1-hydroxycyclohexyl phenyl ketone or phenyl bis(2,4,6-trimethylbenzoyl)-phosphine oxide, whose chemical structures are respectively as shown in (Formula 10) and (Formula 11) below.

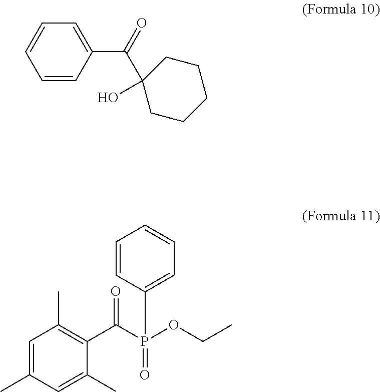 [SMILES: O=C(c1ccccc1)C1(O)CCCCC1 ; CCOP(=O)(C(=O)c1c(C)cc(C)cc1C)c1ccccc1]

In some embodiments, the raw materials of the adhesion layer 152a further include an additive. The additive includes, for example, a surface active agent, a stabilizer, a dye, a solvent, or other materials. In some embodiments, the additive includes, for example, conductive particles, conductive fibers, conductive polymer, or other suitable conductive materials. Therefore, the adhesion layer 152a has an antistatic function. In some embodiments, the additive includes a difunctional acrylic oligomer (for example, an aliphatic urethane diacrylate oligomer). The difunctional acrylic oligomer may improve the bridging properties of the adhesion layer 152a, thereby enhancing chemical resistance and heat resistance of the adhesion layer 152a, and reducing any residual adhesive generated after the adhesion layer 152a is removed. In some embodiments, the additive includes a difunctional monomer (for example, ethoxylated bisphenol A diacrylate, 1,6-hexanediol diacrylate, or a combination thereof). The difunctional monomer may further enhance the bridging strength of the adhesion layer 152a.

In some embodiments, as shown in FIG. 6, FIG. 8, and FIG. 9, a release layer 160 may be formed on the adhesion layer 151b of the adhesive film 151 or the adhesion layer 152a of the adhesive film 152 (for example, the adhesive films 1521 and 1522) to enhance the convenience of use, wherein the release layer 160 is torn off when the bonding process is to be performed. Here, the material of the release layer 160 may be polyethylene terephthalate (PET), polyolefins (PO), a release paper, or the like, and a thickness T7 of the release layer 160 is between 0.038 mm and 0.125 mm (for example, 0.05 mm), but the disclosure is not limited thereto.

In summary, the disclosure may effectively regulate the warping state of the semiconductor structure through the synergistic effect between the pulling force continuously provided by the adhesive film after being bonded to the semiconductor structure and the softening phenomenon of the molding layer after the baking process in the case where the baking process is stopped and the temperature is gradually lowered, so that the upwardly warped semiconductor structure receives the reverse stress during the cooling process and shrinks downward to approach the horizontal state. In this way, warping of the semiconductor structure may be effectively reduced, thereby improving the production yield of the product.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A manufacturing method of a semiconductor device, comprising:
providing a semiconductor structure, wherein the semiconductor structure comprises:
a substrate, having a first surface and a second surface opposite to each other;
an interposer, disposed on the first surface, wherein the interposer comprises a molding layer and a conductive layer buried in the molding layer;
a plurality of chips, disposed on the interposer;
a plurality of external terminals, disposed on the second surface, wherein the chips are electrically connected to the external terminals through the interposer and the substrate;
performing a bonding process, so that an adhesive film covers the external terminals, wherein the adhesive film is used to provide an inward pulling force on the semiconductor structure;
performing a baking process on the semiconductor structure and the adhesive film thereon, wherein a temperature of the baking process is less than 300° C.; and
removing the adhesive film.

2. The manufacturing method of the semiconductor device according to claim 1, wherein before the bonding process is performed, at least one axial tension is provided to the adhesive film to provide the pulling force after the bonding process is performed.

3. The manufacturing method of the semiconductor device according to claim 2, wherein a value range of the tension is between 1 N/cm and 30 N/cm.

4. The manufacturing method of the semiconductor device according to claim 2, wherein the at least one axial direction is an X-axis, a Y-axis, or a combination thereof.

5. The manufacturing method of the semiconductor device according to claim 2, wherein the adhesive film is composed of a first base material and a first adhesion layer, the first adhesion layer is disposed between the substrate and the first base material, and a material of the first base material comprises polyimide.

6. The manufacturing method of the semiconductor device according to claim 1, wherein the adhesive film comprises a regulating layer, a value range of a coefficient of thermal expansion of the regulating layer is between 20 ppm/° C. and 300 ppm/° C., and after the baking process is performed, the regulating layer provides the pulling force.

7. The manufacturing method of the semiconductor device according to claim 6, wherein the adhesive film is composed of a second adhesion layer and the regulating layer, and the adhesive film is bonded to the semiconductor structure through the second adhesion layer.

8. The manufacturing method of the semiconductor device according to claim 7, wherein the regulating layer comprises polyetherimide, polyetheretherketone, polyphenylene sulfide, polyethylene naphthalate, or a combination thereof.

9. The manufacturing method of the semiconductor device according to claim 6, wherein the adhesive film is composed of a second base material, a third adhesion layer, and the regulating layer, the adhesive film is bonded to the semiconductor structure through the third adhesion layer, the third adhesion layer is disposed between the semiconductor structure and the second base material, and the second base material is disposed between the third adhesion layer and the regulating layer.

10. The manufacturing method of the semiconductor device according to claim 9, wherein the second base material comprises polyimide, and the second regulating layer comprises epoxy molding compound, phenolic resin, or a combination thereof.
